(19) United States
(12) Patent Application Publication
(10) Pub. No.: US 2005/0202583 A1
(43) Pub. Date: Sep. 15, 2005

(54) Antistatic film forming composition, and producing method for conductive film pattern, electron source and image display apparatus

(75) Inventors: Yasuko Tomida, Atsugi-shi (JP); Yoko Kosaka, Atsugi-shi (JP); Masahiro Terada, Hadano-shi (JP); Taku Shimoda, Atsugi-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/078,288

(22) Filed: Mar. 14, 2005

(30) Foreign Application Priority Data
Mar. 15, 2004 (JP) 2004-071955

(51) Int. Cl. H01L 21/00

(52) U.S. Cl. 438/48

(57) ABSTRACT

The invention provides a composition including a metal and a photosensitive component, wherein a film pattern formed by subjecting the composition to an exposure to light and a development has a water-repellent property and becomes an electrically resistant film upon baking.

### BACKGROUND OF THE INVENTION

1. Field of the Invention

The present invention relates to a method for producing a conductive film pattern involving a water-repellent film pattern, and more particularly to a producing method for an electron source and an image display apparatus provided with an antistatic film, utilizing such producing method for the conductive film pattern, and a conductive film having an electron emitting portion, and an antistatic film forming composition for use in such producing method.

2. Related Background Art

Since an electron source substrate, which is provided on an insulating substrate with an electron emission device formed by a device film having an electron emitting portion between a pair of device electrodes, shows unstable electron emission characteristics in the electron emission device and a deterioration by a discharge in the electron emission device when the substrate surface is charged, it is already known to form, on the substrate provided with the aforementioned electrodes and a device film prior to the formation of the electron emitting portion, a film by a spray coating method or a Langmuir-Blodgett method utilizing an antistatic film forming liquid containing a constituent of an antistatic film and to bake such film thereby forming an antistatic film (for example, Japanese Patent Application Laid-open Nos. H8-180801 and 2002-358874).

It is also known to form the device film prior to the formation of the electron emitting portion in the aforementioned electric emission device, by depositing a device film forming liquid, prepared by dissolving or dispersing a constituent of the device film in an aqueous medium, as liquid droplets between the device electrode, for example, by an ink jet method and baking such liquid (for example, Japanese Patent Application Laid-open No. 2000-251665).

However, the aforementioned prior producing method for the antistatic film, in which a device film is formed and then a film for forming an antistatic film is formed and baked, requires two baking operations, namely a baking for forming the device film and a baking for forming the antistatic film, thus involving a larger number of steps and leading to an increased production cost.

Also in the aforementioned prior producing method for the device film, the device film forming liquid, deposited between the device electrodes, tends to flow so that the obtained device film becomes unstable in its dimension and thickness and the electron emission device obtained by forming an electron emitting portion in the device film tends to show unstable characteristics.

### SUMMARY OF THE INVENTION

In consideration of the foregoing, an object of the present invention is to provide a producing method for a conductive film pattern, capable of reproducibly and stably providing a conductive film pattern of desired dimension and thickness.

Another object of the present invention is to provide a method capable of reproducibly and stably providing an electron emission film of desired dimension and thickness, and also capable of producing an electron source having plural electron emission films of uniform electron emission characteristics and of satisfactory reproducibility.

Still another object of the present invention is, in forming an electron source provided with an electron emission film and an antistatic film, to provide a method capable of reducing a number of baking operations thereby simplifying a production process and of reproducibly and stably providing an electron emission film of desired dimension and thickness, thereby producing an electron source having plural electron emission films of uniform electron emission characteristics and of satisfactory reproducibility.

The present invention provides a producing method for a conductive film pattern including a step of forming, on a substrate, a film containing a first metal, a photosensitive component and a water-repellent component, a step of subjecting the film to an exposure to light and a development thereby forming a first film pattern having a water-repellent property, a step of providing an area surrounded by the first film pattern on the substrate with a liquid containing a second metal and water thereby forming a second film pattern, and a step of baking the first film pattern and the second film pattern thereby forming a conductive film pattern on the substrate.

The present invention also provides a producing method for an electron source provided, on a substrate, with plural conductive films having electron emitting portions and an antistatic film provided around the plural conductive film, the method including a step of forming, on the substrate, a film containing a first metal, a photosensitive component and a water-repellent component, a step of subjecting the film to an exposure to light and a development thereby forming a precursor film pattern having a water-repellent property of the antistatic film, a step of providing an area surrounded by the precursor film pattern of the antistatic film on the substrate with a liquid containing a second metal and water thereby forming a precursor film pattern of the conductive film, and a step of baking the precursor film pattern of the antistatic film and the precursor film pattern of the conductive film thereby forming the antistatic film and the conductive film on the substrate.

The present invention further provides a composition for an antistatic film containing a metal and a photosensitive component, in which a film pattern formed by subjecting the composition to an exposure to light and a development has a water-repellent property and becomes an electrically resistant film upon baking.

### BRIEF DESCRIPTION OF THE DRAWINGS

FIG. 1 is a view showing an example of a producing method for an electron source of the present invention and is a schematic plan view of a substrate on which element electrodes are formed;

FIG. 2 is a schematic plan view of the substrate shown in FIG. 1, on which Y-direction wirings are further formed;

FIG. 3 is a schematic plan view of the substrate shown in FIG. 2, on which X-direction wirings are further formed;

FIG. 4 is a schematic plan view of the substrate shown in FIG. 3, on which a photosensitive coated film of a composition of the present invention is further formed;

FIG. 5 is a schematic plan view of the substrate, on which the photosensitive coated film shown in FIG. 4 is developed to form a coated film pattern;

FIG. 6 is a schematic plan view of the substrate, on which a device film forming liquid is provided in a device film forming area surrounded by the coated film pattern on the substrate shown in FIG. 5;

FIG. 7 is a schematic cross-sectional view showing a basic configuration about an electron emission device in an electron source obtained by the producing method of the invention;

FIG. 8 is a schematic plan view of FIG. 7;

FIGS. 9A and 9B are charts showing examples of a voltage wave form in a forming process;

FIGS. 10A and 10B are charts showing examples of a voltage wave form in an activation process; and

FIG. 11 is a schematic perspective view showing an image display apparatus utilizing an electron source of the invention.

### DESCRIPTION OF THE PREFERRED EMBODIMENTS

A first aspect of the present invention is an antistatic film forming composition containing a metal and a photosensitive component, in which a film pattern formed by an exposure to light and a development on the composition has a water-repellent property and such film pattern becomes an electrically resistant film upon baking.

A second aspect of the present invention is a producing method for a conductive film pattern including:
a step of forming, on a substrate, a film containing a first metal, a photosensitive component and a water-repellent component;
a step of subjecting the film to an optical exposure and a development to form a first film pattern having a water-repellent property;
a step of providing an area surrounded by the first film pattern with a liquid containing a second metal and water thereby forming a second film pattern; and
a step of baking the first film pattern and the second film pattern thereby forming an electroconductive film pattern on the substrate.

A third aspect of the present invention is a producing method for an electron source provided, on a substrate, with plural conductive films having electron emitting portions and an antistatic film positioned around the plural conductive films, the method including:
a step of forming, on a substrate, a film containing a first metal, a photosensitive component and a water-repellent component;
a step of subjecting the film to an optical exposure and a development thereby forming a precursor film pattern, having a water-repellent property, of the antistatic film;
a step of providing an area surrounded by the precursor film pattern of the antistatic film with a liquid containing a second metal and water, thereby forming a precursor film pattern of the conductive film; and
a step of baking the precursor film pattern of the antistatic film and the precursor film pattern of the conductive film thereby forming the antistatic film and the conductive film on the substrate.

A fourth aspect of the present invention is a producing method for an image display apparatus, characterized in positioning, in a mutually opposed relationship, an electron source produced by the producing method for the electron source of the aforementioned third aspect and a substrate having an image display member which displays an image by an electron irradiation from the electron source.

The antistatic film forming composition (hereinafter represented as “composition”) of the present invention is to form a resistant film by baking a film pattern obtained from the composition, and such resistant film is provided on a substrate that tends to cause an electrostatic charge and advantageously employed as an antistatic film for such substrate surface. A metal in the composition of the invention can be, for example, tin, chromium, indium, tungsten, aluminum, silver or platinum, and is a material capable of forming a high-resistance conductive thin film by forming a metal oxide or a mixture of a metal oxide and another metal, at least after a baking operation to be explained later.

The metal may be dispersed as fine metal particles in a liquid medium such as ethanol, isopropanol or butanol, or dissolved as a metal compound in such liquid medium. An example is a dispersion of fine particles of tin oxide and indium oxide in a liquid medium formed by a mixture of ethanol, isopropanol and butanol.

In case of dissolving in the liquid medium, there is particularly advantageously employed an indium compound or a tin compound which generates a metal oxide by a heat at the baking operation. Examples of such compound include an organic or inorganic salt of indium such as indium formate, indium acetate, indium oxalate, indium nitrate, indium chloride or indium sulfate; a hydrated compound thereof; an indium alkoxide such as indium methoxide, indium ethoxide, indium propoxide, or indium butoxide; an ester thereof with an α- or β-diketone or an α- or β-ketonacid; and a chelate with α- or β-aminoalcohol; an organic or inorganic salt of tin such as tin formate, tin acetate, tin oxalate, tin nitrate, tin chloride or tin sulfate; a hydrated compound thereof; a tin alkoxide such as tin methoxide, tin ethoxide, tin propoxide, or tin butoxide; an ester thereof with an α- or β-diketone or an α- or β-ketonacid; and a chelate with α- or β-aminoalcohol. In particular, a chelate compound formed by coordinating an organic substance to tin is advantageously employed in the present invention.

As a photosensitive component in the composition of the present invention, there is employed a common photosensitive resin of a photodegradable type (in which a coated film insoluble in a developing liquid becomes soluble therein by a light irradiation), or a photosettable type (in which a coated film soluble in a developing liquid becomes insoluble thereby by a light irradiation). Also the photosensitive resin, employed as the photosensitive component, may be of a type having a photosensitive group in a resin structure, or a type formed by a mixture of a resin and a sensitizer, such as a cyclized rubber-bisazide resist. Also in any type of photosensitive resin, another photosensitive component such as a photoreaction initiator or a photoreaction inhibitor may be suitably added.

As the photosensitive resin, there can be employed a known photodegradable type resist for example polymethylvinylketone, polyvinylphenylketone, polysulfone, a diazonium salt such as p-diazodiphenylamine-paraformaldehyde polycondensate, a quinonediazide such as 1,2-naphthoquinone-2-diazide-5-sulfonate isobutyl ester, polymethyl methacrylate, polyphenylmethylsilane or polymethylisopropenyl ketone. Also there can be utilized a mixture of glue, casein, shellac, or polyvinyl alcohol with ammonium bichromate, a mixture of polyvinyl alcohol and a diazo resin, polyvinyl cinnamate, a cyclized rubber-azide system, or a resin system containing a (meth)acrylic monomer and/or a (meth)acrylic oligomer. Such photosensitive resin provides a coated film, formed by coating and drying the composition of the present invention, with a photosensitive property thereby allowing to easily obtain a coated film pattern of an arbitrary shape by a photoresist technology, and also serves to provide a function as a binder and a coating property.

An amount of the aforementioned photosensitive resin is preferably employed in an amount of 1 to 30 parts by weight with respect to 100 parts by weight of the composition of the invention, more preferably 5 to 20 parts by weight. With a deficient amount of the photosensitive resin, it becomes difficult to form a film pattern to be explained later. Also an excessive amount of the photosensitive resin deteriorates a film quality of a resistance film to be obtained by a baking to be explained later, for example an antistatic film, whereby desired electrical characteristics tend to become difficult to obtain.

The composition of the present invention shows a water repellency in a film pattern after a development as will be explained later, and preferably contains a water repellent component. Such water repellent component may be included as one of the aforementioned photosensitive component, or may be externally added for regulating the water repellency of the obtained film pattern.

The water repellent component can, for example, be a silane coupling agent or polysiloxane. Specific examples include tetramethoxysilane, methyltrimethoxysilane, dimethyldimethoxysilane, phenyltrimethoxysilane, tetraethoxysilane, methyltriethoxysilane, trimethylethoxysilane, dimethyldiethoxysilane, phenyltriethoxysilane, hexyltriethoxysilane, hexamethyldisilazane, methyltrichlorosilane, dimethyldichlorosilane, 3-aminopropyltrimethoxysilane, N-2-(aminoethyl)-3-aminopropyltriethoxysilane, dimethyldiacetoxysilane, vinyltrimethoxysilane, 3-glycidoxypropylmethyldiethoxysilane, p-styryltrimethoxysilane, or 3-methacryloxypropyltrimethoxysilane, dimethylpolysiloxane, methylphenylpolysiloxane, methylhydrogenpolysiloxane, amino-denatured polysiloxane, epoxy-denatured polysiloxane, carboxyl-denatured polysiloxane, methacryl-denatured polysiloxane, phenol-denatured polysiloxane, polyether-denatured polysiloxane, alkyl-denatured polysiloxane, or methylstyryl-denatured polysiloxane, In particular, dimethyldiethoxysilane, dimethyldiacetoxysilane or trimethylethoxysilane can be employed advantageously.

In the composition of the present invention, an amount of the water repellent component such as silane coupling agent or polysiloxane mentioned above is preferably 1 to 30 parts by weight with respect to 100 parts by weight of the composition of the invention. With a deficient amount of the water repellent component, the obtained coated film pattern shows, on a surface thereof, a small contact angle to water, thereby resulting in an insufficient diffusion suppressing function for a liquid for forming a second film pattern or a precursor film pattern of a conductive film having an electron emitting portion, to be explained later. Also an excessive amount of the water repellent component deteriorates a film quality of a resistance film, for example an antistatic film, whereby desired electrical characteristics tend to become difficult to obtain.

The composition of the present invention preferably forms a coated film pattern having a surface contact angle to water of 20° or more, more preferably 40° or more, in order that the obtained coated film pattern has an appropriate diffusion suppressing function to a liquid for forming a second film pattern or a precursor film pattern of a conductive film having an electron emitting portion, to be explained later. Also in order that the liquid for a second film pattern or a precursor film pattern of a conductive film having an electron emitting portion, to be explained later, can be satisfactorily provided in an area, on the substrate, surrounded by a film pattern of the aforementioned composition, it is preferable to control the contact angle to water of the surface of the film pattern at twice or larger of the contact angle to water of the substrate surface.

A liquid medium in the composition of the invention for dissolving or dispersing the aforementioned components can be, for example, water, an organic solvent or a mixture thereof. Examples of the organic solvent include an alcohol such as methanol, ethanol, isopropyl alcohol, or butanol; an acetate ester such as ethyl acetate or butyl acetate; a ketone such as acetone, methyl ethyl ketone, diethyl ketone or acetylacetone; an ether such as methoxyethanol, or ethoxyethanol; a hetero compound such as dioxane or tetrahydrofuran; a sulfur compound such as dimethyl sulfoxide; an amine such as ethanolamine, diethanolamine or triethanolamine; an amide such as N,N-dimethylformamide; and an aromatic compound such as toluene or xylene.

Type and composition of the liquid medium can be suitably selected according to the type of the metal, the photosensitive component and the water repellent component to be employed. For example, in case the employed metal is in the form of a metal salt of indium or tin and the photosensitive component is a water-soluble resin, it is preferable to employ water or a mixture of water and an organic solvent as the liquid medium, and to neutralize the salt if necessary thereby changing the metal salt into a hydroxide. On the other hand, in case the employed metal is in the form of a metalorganic compound such as an alkoxide of indium or tin and the photosensitive component is a resin soluble in an organic solvent, it is preferable to employ an organic solvent or a mixture thereof with water as the liquid medium and to hydrolyze the metalorganic compound if necessary to form a hydroxide. In case of such neutralization or hydrolysis, the metal component becomes a hydroxide or an oxide, constituting a dispersion (sol or colloid) of fine particles.

An amount of the aforementioned liquid medium can be suitably selected according to the type of a conductive material to be employed or a precursor, a photosensitive component and a water repellent component, and is generally employed preferably in such a manner that a solid to be dissolved or dispersed constitutes 1 to 30 wt. %. A deficient amount of the liquid medium tends to deteriorate the coating property of the coated film, while an excessive amount of the liquid medium results in a small thickness of the obtained resistant film, for example an antistatic film, thus tending to cause defects in the film.

Also the composition of the present invention may further include, if necessary, an additive such as a sensitizer.

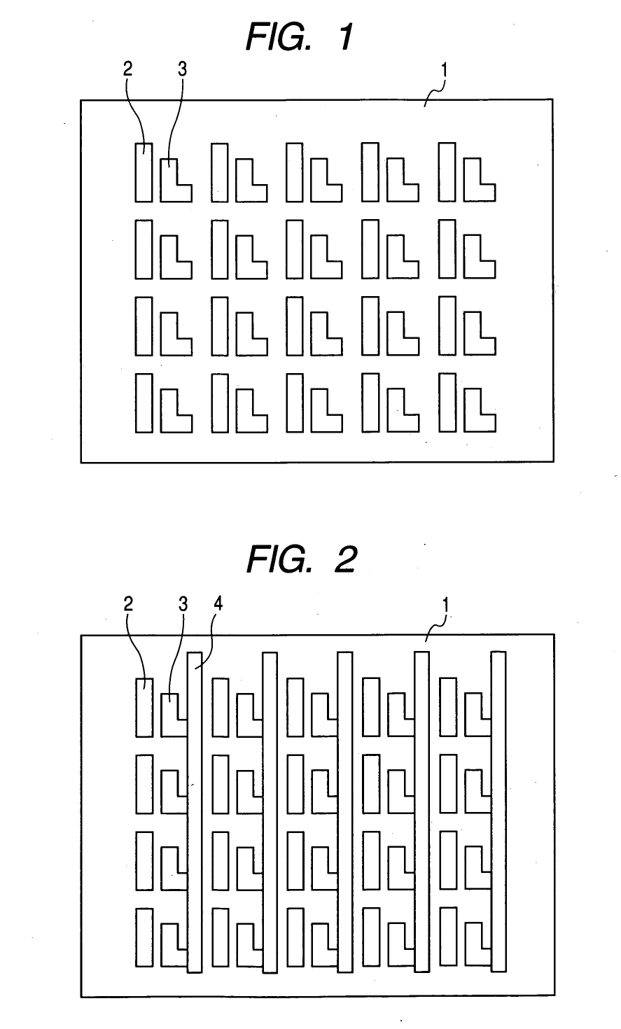

In the following, a producing method for a conductive film pattern of the invention will be explained with reference to FIGS. 1 to 8, by an example of a producing method for an electron source.

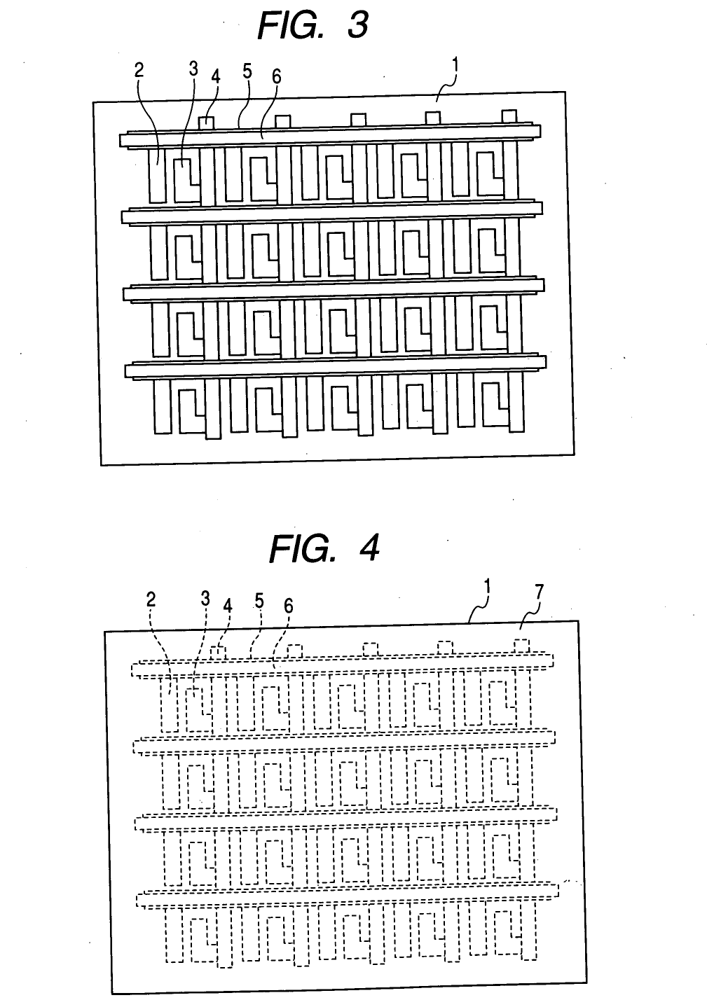

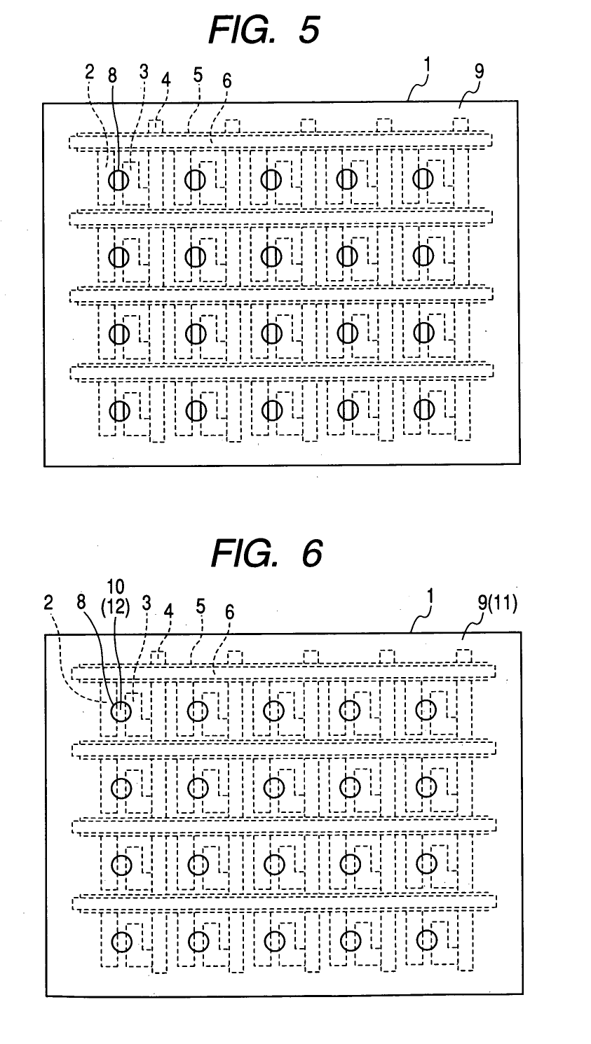

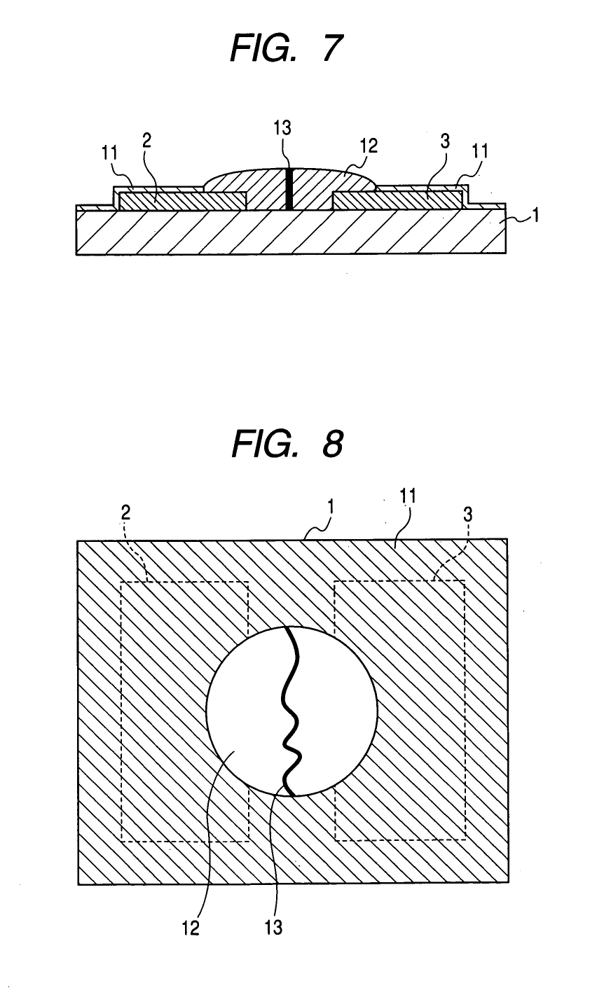

FIGS. 1 to 6 are schematic views showing a producing method for an electron source, in which FIG. 1 is a schematic plan view of a substrate on which element electrodes are formed; FIG. 2 is a schematic plan view of the substrate shown in FIG. 1, on which Y-direction wirings are further formed; FIG. 3 is a schematic plan view of the substrate shown in FIG. 2, on which X-direction wirings are further formed; FIG. 4 is a schematic plan view of the substrate shown in FIG. 3, on which a photosensitive film containing a first metal, a photosensitive component and a water repellent component is further formed; FIG. 5 is a schematic plan view of the substrate, on which the photosensitive film shown in FIG. 4 is developed to form a precursor film pattern (first film pattern) of an antistatic film; FIG. 6 is a schematic plan view of the substrate, on which a liquid containing a second metal and water is provided in an area surrounded by the precursor film pattern (first film pattern) of the antistatic film on the substrate shown in FIG. 5, thereby forming a precursor film pattern (second film pattern) of a conductive film in which an electron emitting portion is to be formed; FIG. 7 is a schematic cross-sectional view showing a basic configuration about an electron emission device in an electron source obtained by the producing method of the invention; and FIG. 8 is a schematic plan view of FIG. 7.

At first, as shown in FIG. 1, device electrodes 2, 3 in pairs are formed on a substrate 1. A number of the device electrodes 2, 3 is not particularly restricted, but, in case of producing an electron source for use in an image display apparatus to be explained later, the device electrodes 2, 3 are formed in plural pairs in order to obtain plural electron emission devices to be matrix driven.

The substrate 1 can be constituted, for example, of a quartz glass, a glass with a reduced amount of impurities such as Na, a soda-lime glass, a SiO₂-coated glass plate or a ceramic plate such as of alumina.

A size and a thickness of the substrate 1 can be suitably selected according to a number of the electron emission devices to be provided thereon, a design shape of the individual electron emission device and, in case the substrate 1 constitutes a part of a vacuum envelope of the image display apparatus, mechanical conditions such as a pressure-resistant structure.

A material for the device electrodes 2, 3 can be an ordinary electroconductive material, for example, a metal or an alloy of Ni, Cr, Au, Mo, Pt, Ti, Al, Cu and Pd, a printed conductor constituted of a metal or a metal oxide such as of Pd, As, Ag, Au, RuO₂ or Pd—Ag and a glass or the like, or a transparent conductor such as ITO. For forming the electrodes, there can be selected, according to the materials to be employed, a combination of an ordinary film forming method such as sputtering and a photolithographic etching technology, or a printing method such as offset printing or screen printing.

Also a commercially available paste containing metal particles such as of Pt may be employed for forming the device electrodes 2, 3 by printing such as offset printing, following by baking. For obtaining a more precise pattern, the electrodes can also be formed by printing a photosensitive paste containing, for example, Pt by a screen printing method or the like, followed by an exposure through a photomask, a development and a baking.

The device electrodes 2, 3 preferably have a thickness within a range from several hundred Angstroms to several micrometers. A gap, a length and a shape of the device electrodes 2, 3 are designed according to the purpose of use of the electron source substrate, but a gap of the device electrodes 2, 3 is generally within a range from several thousand Angstroms to 1 mm, and, in consideration of a voltage to be applied between the device electrodes 2, 3, preferably within a range of 1 to 100 μm. Also the device electrodes 2, 3 preferably have a length (length perpendicular to an opposing direction) within a range of several to several hundred micrometers in consideration of the resistance of the device electrodes 2, 3 and the electron emission characteristics thereof.

Then, as shown in FIG. 2, a Y-direction wiring (lower wiring) 4 to be employed as a common wiring is formed with an electrical connection with either device electrode 3 (or 2). The Y-direction wiring 4 can be formed by a method similar to that for the device electrodes 2, 3, but is generally formed by printing a conductive paste (for example silver paste) by a printing method followed by a baking.

After the formation of the Y-direction wiring 4, an interlayer insulation film 5 is formed in a direction crossing the Y-direction wiring as shown in FIG. 3, and, along such interlayer insulation film 5, an X-direction wiring 6 (upper wiring) to be employed as a signal electrode is formed with an electrical connection with the other device electrode 2 (or 3). A connection between the X-direction electrode 6 and the device electrode 2 (or 3) is achieved by forming a contact hole (not shown) in the interlayer insulation layer 5 on the device electrode 2 (or 3) and forming the X-direction wiring 6 in a state connected with the device electrode 2 (or 3) through such contact hole.

The interlayer insulation layer 5 can be formed by printing a paste constituted, for example, of PdO as a principal component and a glass binder by a screen printing method of the like and baking such paste. Also the X-direction wiring 6 can be formed by a method similar to that for the Y-direction wiring 4.

Then an antistatic film forming composition of the present invention is coated and dried on the entire surface of the substrate 1, on which the device electrodes 2, 3, the Y-direction wiring 4, the interlayer insulation layer 5 and the X-direction wiring 6 are formed, thereby forming a photosensitive coated film 7 containing a first metal, a photosensitive component and a water repellent component as shown in FIG. 4.

The coating of the antistatic film forming composition may be executed after the formation of the device electrodes 2, 3 and before the formations of the Y-direction wiring 4 to the X-direction wiring 6, but is preferably executed after such formations since the photosensitive coated film 7 can be easily formed not only on the exposed surface of the substrate 1 but also on the interlayer insulation layer 5 usually exposed on both sides of the X-direction wiring 6, whereby the exposed portions of the interlayer insulation layer 5 can also be covered by an antistatic film 11 (cf. FIGS. 6 to 8) to be explained later.

The antistatic film forming composition can be coated on the substrate 1, for example, by a spin coating method, a roll coating method, a dip coating method, a die coating method, a bead coating method or a spray coating method. A coating amount of the antistatic film forming composition can be regulated according to a film thickness and a resistance of the antistatic film 11 (FIGS. 6 to 8) to be obtained. After the antistatic film forming composition is coated on the substrate 1, it is preferable to heat at least a coated surface thereby promptly drying the coated film and obtaining the photosensitive coated film 7.

The photosensitive coated film 7 can be patterned utilizing a photodegradable property or a photosettable property. The photosensitive coated film 7 is exposed to light in a desired portion and developed, whereby the photosensitive coated film 7 is eliminated to form an aperture 8 in an area for forming a precursor film (second film pattern) of the conductive film (hereinafter called device film) 12 having an electron emitting portion (cf. FIGS. 6 to 8), and thus constitutes a precursor film pattern (first film pattern) 9 of the antistatic film surrounding the area of each device film 12. The aperture 8 is so formed, between paired device electrodes 2 and 3, as to expose a part of mutually opposed sides of the device electrodes 2, 3 and the surface of the substrate 1 in the vicinity.

The aforementioned exposure and development are executed by placing a photomask (not shown) of a predetermined pattern on the photosensitive coated film 7, irradiating an ultraviolet light through the photomask to expose, in case the photosensitive coated film 7 is a photodegradable type, a portion corresponding to an area for forming the device film (cf. FIGS. 6 to 8), or, in case the photosensitive coated film 7 is a photosettable type, a portion other than the area for forming the device film and then eliminating, with a developer solution, a portion degraded by exposure or remaining unhardened after the exposure thereby forming an aperture 8. The developer solution is selected, for example, according to the type of the photosensitive resin employed as the photosensitive component. For a photodegradable photosensitive resin, the developer solution can be an aqueous solution of an organic alkali such as tetramethylammonium hydroxide, or diethanolamine, or an inorganic alkali such as sodium carbonate, sodium hydroxide or potassium hydroxide, and, for a photosettable photosensitive resin, the developer solution can be same as the liquid medium employed in the antistatic film forming composition.

The aperture 8 is illustrated as a circular shape, but it may also be formed in another shape such as a square shape, a rectangular shape or an oval shape.

The first film pattern 9 formed through the exposure and the development shows a water repellent property. The first film pattern 9 preferably has, on a surface thereof, a contact angle to water of 20° or larger, in order to obtain an adequate diffusion suppressing function to a device film forming liquid 10 to be explained later (cf. FIG. 6), more preferably a contact angle to water of 40° or larger.

After the formation of the first film pattern 9 as described above, a device film forming liquid formed by dissolving or dispersing a constituent of the device film 12 in an aqueous medium, namely a liquid 10 containing a second metal and water, is provided in the aperture 8 in each area for forming the device film 12, so as to cover the portions of the device electrodes 2, 3 exposed in the aperture 8, as shown in FIG. 6.

A material constituting the device film 12 can be a metal such as Pd, Pt, Ru, Ag, Au, Ti, In, Cu, Cr, Fe, Zn, Sn, Ta, W or Pb, an oxide such as PdO, SnO₂, In₂O₃, PbO or Sb₂O₃, a boride such as HfB₂, ZrB₂, LaB₆, CeB₆, YB₄ or GbB₄, a carbide such as TiC, ZrC, HfC, TaC or WC, or a nitride such as TiN, ZrN or HfN, among which Pd is preferred. The aqueous medium mentioned above is a solvent or a dispersant containing water by 50 wt. % or more, and main contain, within a range less than 50 wt. %, a lower alcohol such as methyl alcohol or ethyl alcohol for increasing the drying speed or a component for promoting dissolution or stabilization of the aforementioned metalorganic compound. However, for the purpose of reducing the environmental burden, the water content is preferably 70 wt. % or higher and further preferably 80 wt. % or higher.

The device film forming liquid 10 is formed by dissolving or dispersing the aforementioned metal or the like in the aforementioned aqueous medium, and can, for example, be an aqueous solution of a metalorganic compound containing the metal mentioned above. More specifically, it can be an aqueous solution containing an ethanolamine complex, such as palladium acetate-ethanolamine complex (PA-ME), palladium acetate-diethanol complex (PA-DE), palladium acetate-triethanol complex (PA-TE), palladium acetate-butylethanolamine complex (PA-BE), or palladium acetate-dimethylethanolamine complex (PA-DME).

The deposition of the device film forming liquid 10 into the aperture 8 is preferably executed by an ink jet method in which the device film forming liquid 10 is discharged as a liquid droplet from an ink jet apparatus, because it is easier in such method to avoid deposition of the device film forming liquid 10 in an unnecessary position, but it can also be achieved by a spin coating method or a dipping method in case the coated film pattern 9 has a water repellency capable of eliminating a surface sticking of the device film forming liquid 10. Also since the coated film pattern 9 has a water repellency and surrounds the aperture 8 where the device film 12 is to be formed, the device film forming liquid 10 deposited in the aperture 8 can be prevented from a diffusion by a flow and can therefore be provided in a state contained within the aperture 8. Particularly in case of the ink jet method, as the surface is water repellent except for the area where the device film forming liquid 10 is provided as a liquid droplet by the ink jet apparatus, there can be secured a large margin in the precision of deposition of the device film forming liquid 10 utilizing an aqueous medium, thus providing advantages in the production yield and the production cost of the electron source substrate.

Since the effect of the aforementioned coated film pattern 9 becomes easier to obtain as the contact angle to water of the surface thereof becomes larger than the contact angle to water of the substrate surface exposed in the aperture 8, it is preferable that the contact angle of the surface of the coated film pattern 9 is twice of or larger than that of the surface of the substrate 1.

After the device film forming liquid 10 is deposited in the aperture 8 constituting an area for forming the device film 12, a baking operation is executed to eliminate a residual medium and an organic component in the coated film pattern 9 and the device film forming liquid 10 and to generate metals and/or metal oxides contained therein whereby an antistatic film 11 can be formed from the coated film pattern 9 and also a device film 12 can be formed from the device film coating liquid 10. In this manner a collective baking is rendered possible for the antistatic film 11 and the device film 12, thus being advantageous in process and in cost.

Thus formed antistatic film 11 preferably has a surface resistance of 1×10⁹ to 1×10¹² Ω/cm², more preferably 5×10⁹ to 10¹² Ω/cm², in order to prevent charging of an insulating portion such as the substrate 1 and to suppress a leak current generated between the device electrodes 2, 3 through the antistatic film 11. A surface resistance of the antistatic film 11 lower than 1×10⁹ Ω/cm² tends to generate a detrimental influence on the electron emission characteristics by the leak current, and a surface resistance larger than 1×10¹² Ω/cm² tends to result in an insufficient antistatic ability for the insulating part.

The device film 11 is formed in a bridging state between the device electrodes 2, 3. A thickness of the device film 11 is suitably selected in consideration of a step coverage on the device electrodes 2, 3, a resistance between the device electrodes 2, 3 and a condition of a forming process to be explained later, but is preferably within a range from several to several thousand Angstroms, particularly preferably 10 to 500 Angstroms.

The resistance of the device film 11, in a state prior to a forming process to be explained later (state prior to the formation of an electron emitting portion 13 (cf. FIGS. 7 and 8)), is preferably of a certain magnitude in order to facilitate such forming process, and is preferably within a specific range of 1×10³ to 1×10⁷ Ω/□. On the other hand, after the forming process (after the formation of the electron emitting portion 13), the device film 11 desirably has a low resistance in order that a sufficient voltage can be applied through the device electrodes 2, 3 to the electron emitting portion 13. It is therefore preferable to form the device film 11 as a metal oxide thin film having a sheet resistance of 1×10³ to 1×10⁷ Ω/□ and to reduce it after the forming process to obtain a metal thin film of a lower resistance. Therefore the resistance of the device film 11 in a final state is not particularly restricted in a lower limit value. The resistance of the device film 11 mentioned herein means a sheet resistance measured within an area not including the electron emitting portion 13.

After the device electrodes 2, 3, the Y-direction wiring 4, the interlayer insulation layer 5, the X-direction wiring 6, the antistatic film 11 and the device film 12 are formed on the substrate 1 as explained above, a forming process is applied to form an electron emitting portion 13 in the device film 12 as shown in FIGS. 7 and 8, and an activation process is preferably executed to obtain an electron source substrate.

On thus obtained electron source substrate, as shown in FIGS. 7 and 8, there is formed an electron emission device by a pair of device electrodes 2, 3 formed on the substrate 1 and a device film 12 provided bridging the device electrodes 2, 3 and including an electron emitting portion 13, and the substrate 1 is covered by the antistatic film 11 excluding an area on the device film 12 including the electron emitting portion 13 in the electron emission device.

In the following there will be explained a forming process and an activation process mentioned in the foregoing.

The forming process is an energizing process for forming an electron emitting portion 13 in the device film 12 as shown in FIGS. 7 and 8, and is achieved by passing a current between the device electrodes 2, 3 from an unillustrated power source under a predetermined vacuum, thereby forming a gap (fissure) by a structural change in the device film 12. Such gap constitutes the electron emitting portion 13, and electrons are emitted from such gap area by applying a voltage between the device electrodes 2, 3 after the forming process. Under a predetermined voltage, the electron emission takes place also from the vicinity of the gap formed by the forming process, but the electron emission efficiency is still very low in this state. An activation process to be explained later is executed for improving the electron emission efficiency.

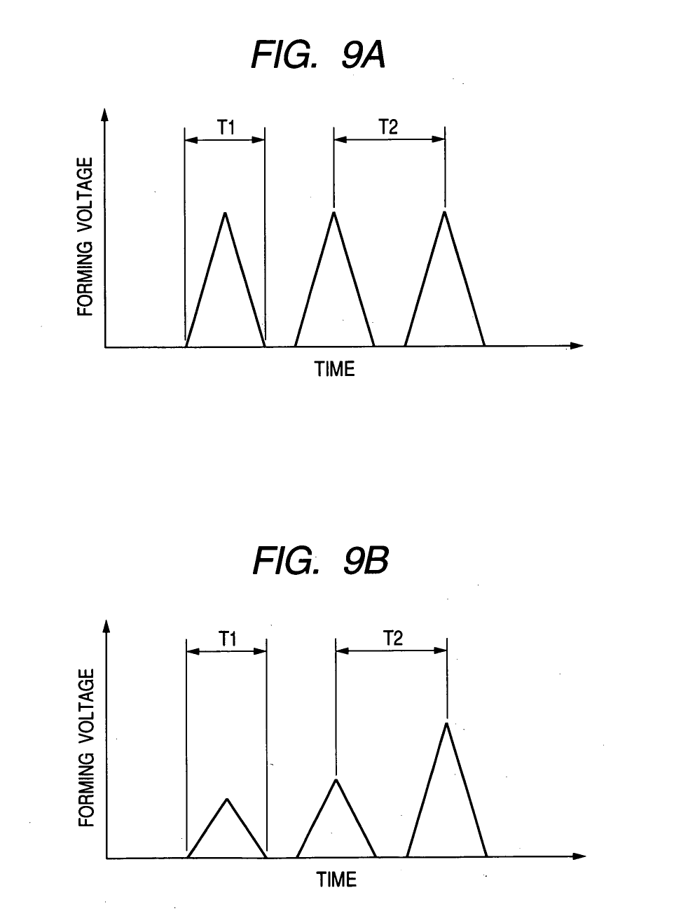

Examples of a voltage wave form employed for the forming process are shown in FIGS. 9A and 9B. There is particularly preferred a pulsed wave form. There can be employed a method of consecutively applying pulses of a constant pulse height voltage, as shown in FIG. 9A, and a method of applying pulses of increasing pulse heights as shown in FIG. 9B.

At first there will be explained a case of applying pulses of a constant pulse height with reference to FIG. 9A, in which T1 and T2 respectively indicate a pulse width and a pulse interval in the voltage wave form. Usually, T1 is selected within a range of 1 μsec to 10 msec, while T2 is selected within a range of 10 μsec to 100 msec. A wave height of the triangular wave (peak voltage at the forming process) is selected suitably according to the shape of the electron emission device. Under such conditions, a voltage application is executed for example for a period of several seconds to several tens of minutes. The pulsed wave form is not limited to a triangular wave but there can be employed any desired wave form such as a rectangular wave.

In the following, there will be explained a case of applying pulses of increasing pulse height with reference to FIG. 9B, in which T1 and T2 have same meanings as in FIG. 9A. A wave height of the triangular wave (peak voltage at the forming process) can be increased, for example, by a step of about 0.1 V.

The forming process can be executed under a resistance determination by measuring a current (device current) flowing between the device electrodes 2, 3 during the pulsed voltage application, and terminated when the resistance becomes for example 1 MΩ or higher.

As explained above, the electron emission efficiency in this state is very low. It is therefore desirable to execute a process called activation, in order to increase the electron emission efficiency.

This activation process can be executed by repeatedly applying a pulsed voltage between the device electrodes 2, 3 under an appropriate vacuum containing an organic compound. Then a gas containing carbon atoms is introduced to deposit carbon or a carbon compound derived therefrom as a carbon film in the vicinity of the aforementioned electron emitting portion 13.

As an example of this process, tolunitrile employed as a carbon source is introduced through a slow-leak valve into a vacuum chamber and is maintained at a pressure of about 1.3×10⁻⁴ Pa. A pressure of the introduced tolunitrile is influenced to a certain extent by a shape of a vacuum apparatus or members employed therein but is advantageously within a range of about 1×10⁻⁵ to 1×10⁻² Pa.

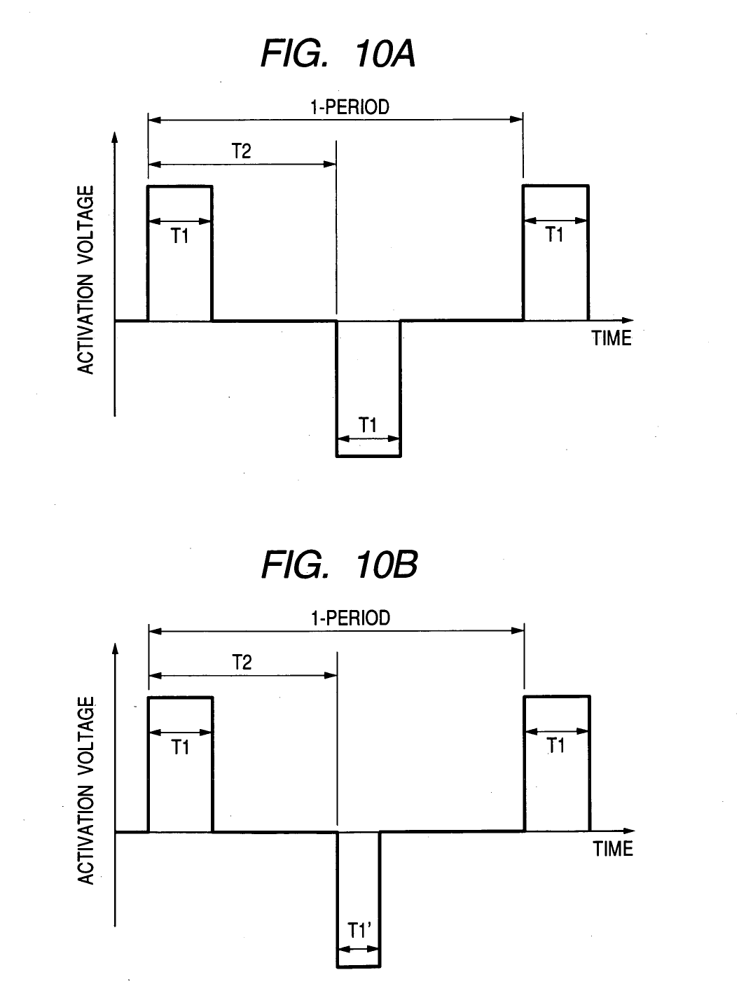

FIGS. 10A and 10B show preferred examples of a voltage application employed in the activation process. A maximum applied voltage is suitably selected within a range of 10 to 20 V.

In FIG. 10A, T1 indicates a pulse width of positive and negative voltage wave forms, while T2 indicates a pulse interval, and positive and negative voltages are set at a same absolute value. In FIG. 10B, T1 and T1′ respectively indicate pulse widths of positive and negative voltage wave forms (T1>T1′), while T2 indicates a pulse interval, and positive and negative voltages are set at a same absolute value.

The activation process is executed by providing an anode in an opposed relationship to the electron emission device, and applying a voltage between the device electrodes 2, 3 while measuring an emission current emitted as an electron beam from the electron emitting portion 13, and the process is terminated when the emission current substantially reaches a saturation, by terminating the current and closing the slow-leak valve.

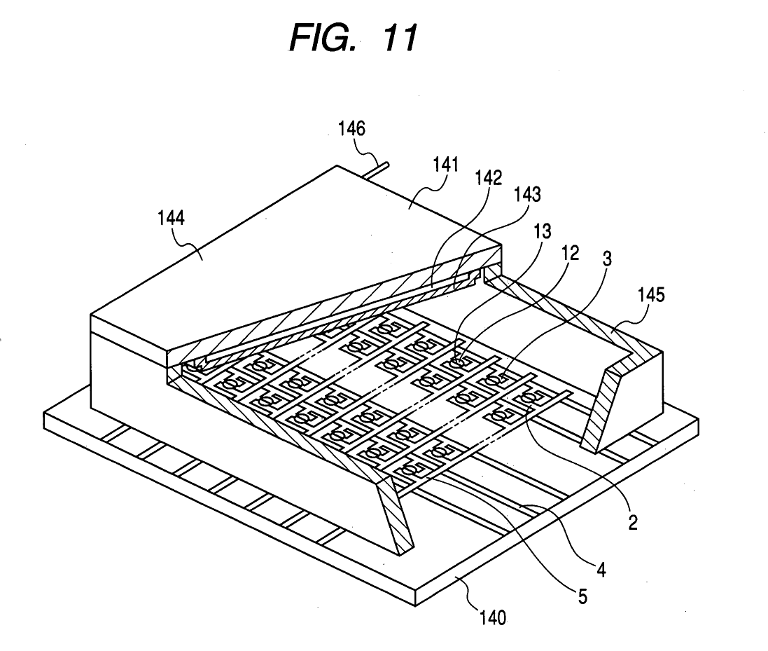

In the following, there will be explained, with reference to FIG. 11, an example of an image forming apparatus which executes an image display utilizing the electron source substrate prepared in the above-described manner. In FIG. 11, the antistatic film is omitted.

In the image forming apparatus shown in FIG. 11, the electron source substrate prepared as explained above is positioned as a rear plate 140. In an opposed relationship to the rear plate 140, there is provided a face plate 144 bearing, on a transparent insulating substrate 141 such as a glass, a phosphor film 142, a metal back 143 etc. 145 indicating a supporting frame. The rear plate 140, the supporting frame 145 and the face plate 144 are sealed for example with frit glass to constitute a panel-shaped closed envelope.

A space enclosed by the rear plate 140, the supporting frame 145 and the face plate 144 is made a vacuum atmosphere. Such vacuum atmosphere can be formed by providing the rear plate 140 or the face plate 144 with an exhaust pipe and sealing off the exhaust pipe after the interior is evacuated, but can be formed more easily by sealing the rear plate 140 and the face plate 144 together with the supporting frame 145 in a vacuum chamber.

An image display can be achieved by connecting a driving circuit for driving the electron emission device to the image forming apparatus, applying a voltage between desired device electrodes 2, 3 through the Y-direction wiring 4 and the X-direction wiring 6 to generate electrons from the electron emitting portion 13, and applying a high voltage to the metal back 143 serving as an anode from a high voltage terminal 146 thereby accelerating the electron beam and causing it to collide with the phosphor film 142.

A large-sized panel-shaped closed envelope having a sufficient strength to the atmospheric pressure can be formed by providing an unillustrated support member, called spacer, between the face plate 144 and the rear plate 140.

The electron emission device provided with the device film 12 having the electron emitting portion 13 between the device electrodes 2, 3 is called a surface conduction electron emission device, in which, in the basic characteristics thereof, the electrons emitted from the electron emitting portion 13 are controlled by a wave height and a width of a pulsed voltage applied between the opposed device electrodes 2, 3 at or above a threshold voltage, and the current is also controlled at an intermediate value, so that a halftone display is made possible. Also in case of arranging a plurality of electron emission devices as in the present embodiment, an appropriate voltage can be applied to each arbitrary electron emission device by determining a selected line by a scanning line signal in each line and by applying the aforementioned pulsed voltage to individual electron emission device through each information signal line, thereby turning on an arbitrary electron emission device.

### EXAMPLES

In the following, the present invention will be clarified further by examples, but the present invention is not limited to such examples but is subject to replacement of components and changes in designing within an extent that the objects of the present invention can be attained.

### Example 1

(Formation of Device Electrode: FIG. 1)

As a substrate 1, there was employed a glass of a thickness of 2.8 mm with a low alkali content (PD-200, manufactured by Asahi Glass Co.), on which an SiO₂ film of a thickness of 100 nm was coated and baked as a sodium blocking layer.

On the substrate 1, films of titanium (thickness: 5 nm) as an undercoat layer and platinum (thickness: 40 nm) were formed in succession by sputtering, then a photoresist was coated thereon and a photolithographic patterning was conducted by an exposure, a development and an etching to form the device electrode 2, 3 (cf. FIG. 3). In the present example, the device electrodes 2, 3 had a gap of 10 μm and a length of 100 μm in a direction perpendicular to a mutually opposing direction.

(Formation of Y-Direction Wiring: FIG. 2)

A Y-direction wiring (lower wiring) 4 as a common wiring was formed by a line-shaped pattern, which is in contact with a device electrode 3 and connects the plural device electrodes 3. An Ag photopaste ink was screen printed, dried, exposed in a predetermined pattern and developed. Then it was baked at a temperature of about 480° C. to obtain the Y-direction wiring 4. The Y-direction wiring 4 had a thickness of about 10 μm and a width of about 50 μm. An end portion was formed with a larger width in order to be used as a lead electrode.

(Formation of Interlayer Insulation Layer: FIG. 3)

An interlayer insulation layer 5 was formed for a mutual insulation between the Y-direction wiring 4 prepared above and an X-direction wiring 6 to be formed next. The interlayer insulation layer 5 was formed in such a manner as to cover a crossing portion of the X-direction wiring 6 to be formed next and the Y-direction wiring 4 prepared above, with a contact hole (not shown) formed in a position corresponding to each device electrode 2 for enabling an electrical connection between the X-direction wiring 6 and the device electrode 2.

More specifically, a photosensitive glass paste principally constituted of PbO was screen printed, then exposed and developed. This process was repeated four times, and the entire layer was then baked at a temperature of about 480° C. The interlayer insulation layer 5 had an entire thickness of about 30 μm, and a width of 150 μm.

(Formation of X-Direction Wiring: FIG. 3)

On the stripe-shaped interlayer insulation layer 5 prepared above, an Ag paste ink was screen printed and dried. This process was repeated twice, and the paste ink was baked at a temperature of about 480° C. to form an X-direction wiring (upper wiring) 6. The X-direction wiring 6 crosses the Y-direction wiring 4 across the interlayer insulation layer 5, and is connected with the device electrode 2 through the contact hole provided in the interlayer insulation layer.

The X-direction electrode functions as a scanning electrode in a driven state, and had a thickness of about 15 μm. Though not illustrated, a lead terminal to an external driving circuit was prepared in a similar method.

(Formation of Coated Film Pattern: FIGS. 4 and 5)

A mixture of an ultraviolet-degradable photosensitive resin and a chelate complex of carboxylic acid-coordinated tin compound was prepared and, after an addition of diacetoxydimethylsilane by 20 wt. %, was spin coated on the sufficiently cleaned substrate 1. It was then dried for 3 minutes at 120° C. on a hot plate to obtain a photosensitive coated film 7, which was subjected to a proximity exposure for 20 seconds through a negative photomask to a light of an ultra high pressure mercury lamp (illumination intensity: 8.0 W/cm²), then developed for 1 minute with tetramethylammonium hydroxide (0.3 wt. %), rinsed with water and dried (120° C., 3 minutes) to obtain a tin-containing coated film pattern 9 having an aperture 8 of 10×30 μm. The coated film pattern 9 had a thickness of 115 nm. Also a contact angle to water, measured on the surface of the coated film pattern 9 and on the surface of the substrate 1 exposed in the aperture 8 respectively in 30 points, was 75° in average with a fluctuation of 6% on the coated film pattern 9, and 6° in average with a fluctuation of 5% on the substrate 1.

(Deposition of Device Film Forming Liquid: FIG. 6)

Then a device film forming liquid 10 was deposited in the aperture 8 of the coated film pattern 9.

In the present example, in order to obtain a palladium film as the device film 12, a palladium-proline complex was dissolved with a concentration of 0.47 wt. % in an aqueous solution of water and isopropyl alcohol (IPA) (85:15) to obtain, with some other additives, an organic palladium-containing solution (device film forming liquid 10). The device film forming liquid 10 was deposited as a liquid droplet, by an ink jet apparatus utilizing a piezo element as a droplet deposition apparatus, onto the aperture 8 of the coated film pattern 9. The palladium compound solution serving as the device film forming liquid 10 was repelled by the coated film pattern 9 and could be selectively provided on the surface of the substrate 1 exposed in the aperture 8.

(Formation of Antistatic Film and Device Film: FIG. 6)

The substrate 1, on which the device film forming liquid 10 was deposited, was heated for 60 minutes in an oven of 380° C. under an atmospheric pressure, thereby simultaneously preparing a device film 12 formed by a decomposition of the palladium compound on the substrate 1 and therearound an antistatic film 11 of tin oxide formed by baking the coated film pattern 9. The device film 12 of palladium oxide had a thickness of 10 nm at maximum, while the antistatic film 11 of tin oxide had a thickness of 28 nm. An antistatic film of tin oxide of a thickness of 28 nm, prepared on another glass plate, showed a sheet resistance of 2×10¹⁰ Ω/□ in vacuum.

The substrate 1, subjected to the above-described formations of the device electrodes 2, 3, the Y-direction wiring 4, the interlayer insulation layer 5, the X-direction wiring 6, the antistatic film 11 and the device 12 prior to the formation of the electron emitting portion 13 (cf. FIGS. 7 and 8), was subjected to a forming process and an activation process as explained above to obtain an electron source substrate of satisfactory electron emission characteristics without a leak current. The obtained electron source substrate showed, under a voltage application of 12 V between the device electrodes 2, 3, an emission current of 0.5 μA in average and an electron emission efficiency of 0.14% in average. Also the electron emission devices were satisfactory in uniformity, with a fluctuation in the emission current in a satisfactory level of 4.8% among the electron emission devices.

### Example 2

Processes from the formation of the device electrodes 2, 3 to the formation of the X-direction wiring 6 were conducted in the same manner as in Example 1, and then steps from the formation of a coated film pattern 9 to the formation of an antistatic film 11 and a device film 12 were conducted in the following manner.

For forming a coated film pattern 9, a mixture of an ultraviolet-settable photosensitive resin and a chelate complex of carboxylic acid-coordinated tin compound doped with antimony by 5 mol. % was prepared and, after an addition of trimethylethoxysilane by 25 wt. %, was spin coated on the sufficiently cleaned substrate 1. It was then dried for 3 minutes at 120° C. on a hot plate to obtain a photosensitive coated film 7, which was subjected to a proximity exposure for 10 seconds through a positive photomask to a light of an ultra high pressure mercury lamp (illumination intensity: 8.0 mW/cm²), then developed for 2 minutes with tetramethylammonium hydroxide (0.3 wt. %), rinsed with water and dried (120° C., 3 minutes) to obtain a coated film pattern 9, containing an antimony-doped tin compound, having a circular aperture 8 of a diameter of 70 μm. The coated film pattern 9 had a thickness of 28 nm. Also a contact angle to water, measured on the surface of the coated film pattern 9 and on the surface of the substrate 1 exposed in the aperture 8 respectively in 30 points, was 62° in average with a fluctuation of 5% on the coated film pattern 9, and 5° in average with a fluctuation of 4% on the substrate 1.

Then a device film forming liquid 10, similar to that in Example 1, was deposited as a liquid droplet, by an ink jet apparatus utilizing a piezo element as in Example 1, onto the aperture 8 of the coated film pattern 9. The palladium compound solution serving as the device film forming liquid 10 was repelled by the coated film pattern 9 and could be selectively provided on the surface of the substrate 1 exposed in the aperture 8.

The substrate 1, on which the device film forming liquid 10 was deposited, was heated for 60 minutes in an oven of 380° C. under an atmospheric pressure, thereby simultaneously preparing a device film 12 formed by a decomposition of the palladium compound on the substrate 1 and therearound an antistatic film 11 of antimony-doped tin oxide formed by baking the coated film pattern 9. The device film 12 of palladium oxide had a thickness of 8 nm at maximum, while the antistatic film 11 of antimony-doped tin oxide had a thickness of 6 nm. An antistatic film of antimony-doped tin oxide of a thickness of 8 nm, prepared on another glass plate, showed a sheet resistance of 5×10¹² Ω/□ in vacuum.

The substrate 1, subjected to the above-described formations of the device electrodes 2, 3, the Y-direction wiring 4, the interlayer insulation layer 5, the X-direction wiring 6, the antistatic film 11 and the device 12 prior to the formation of the electron emitting portion 13 (cf. FIGS. 7 and 8), was subjected to a forming process and an activation process as explained above to obtain an electron source substrate of satisfactory electron emission characteristics without a leak current. The obtained electron source substrate showed, under a voltage application of 12 V between the device electrodes 2, 3, an emission current of 0.6 μA in average and an electron emission efficiency of 0.15% in average. Also the electron emission devices were satisfactory in uniformity, with a fluctuation in the emission current in a satisfactory level of 5.0% among the electron emission devices.

The photosensitive resin composition of the present invention for forming the antistatic film can form an arbitrary coated film pattern by a photoresist technology, thereby allowing to provide an antistatic film, obtained by baking such coated film pattern, with arbitrary range and shape. Also the obtained coated film pattern, having a water repellency, can be utilized as a mold for defining a coating area of a device film forming liquid, in preparing a device film with a device film forming liquid in which a component of the device film is dissolved or dispersed in an aqueous medium.

In the producing method of the invention for the electron source substrate, the device film forming liquid, being deposited in an area surrounded by a water-repellent coated film pattern, can be retained in such surrounded area whereby the device film can be easily prepared with uniform size and thickness thus stabilizing the characteristics of the obtained electron emission device. Also a single baking operation after the deposition of the device film forming liquid in the area surrounded by the coated film pattern before baking allows to simultaneously form the antistatic film and the device film. Such method allows to reduce the number of the baking operation in comparison with the prior technology in which a baking for forming the device film and a baking for forming the antistatic film are executed separately, thereby achieving a cost reduction through a simplified process.

This application claims priority from Japanese Patent Application No. 2004-071955 filed on Mar. 15, 2004, which is hereby incorporated by reference herein.

1. A composition comprising a metal and a photosensitive component, wherein a film pattern formed by subjecting the composition to an exposure to light and a development has a water-repellent property and becomes an electrically resistant film upon baking.

2. A composition according to claim 1, further comprising a liquid for dissolving or dispersing the metal and the photosensitive component.

3. A composition according to claim 2, wherein the film pattern is formed by subjecting the composition to a drying, an exposure to light and a development.

4. A composition according to claim 1, further comprising a silane coupling agent or polysiloxane.

5. A composition according to claim 1, wherein a surface of the film pattern having a water-repellent property has a contact angle to water of 20° or larger.

6. A composition according to claim 1, wherein a surface of the film pattern having a water-repellent property has a contact angle to water of 40° or larger.

7. A producing method for a conductive film pattern comprising steps of:
forming, on a substrate, a film containing a first metal, a photosensitive component and a water-repellent component;
subjecting the film to an exposure to light and a development thereby forming a first film pattern having a water-repellent property;
providing an area surrounded by the first film pattern on the substrate with a liquid containing a second metal and water thereby forming a second film pattern; and
baking the first film pattern and the second film pattern thereby forming a conductive film pattern on the substrate.

8. A producing method for a conductive film pattern according to claim 7, wherein a surface of the first film pattern has a contact angle to water equal to or larger than twice of a contact angle to water of a surface of the substrate.

9. A producing method for a conductive film pattern according to claim 7, wherein the liquid containing the second metal and water is provided by an ink jet method.

10. A producing method for an electron source provided, on a substrate, with plural conductive films having electron emitting portions and an antistatic film formed around the plural conductive film, the method comprising steps of:
forming, on the substrate, a film containing a first metal, a photosensitive component and a water-repellent component;
subjecting the film to an exposure to light and a development thereby forming a precursor film pattern having a water-repellent property of the antistatic film;
providing an area surrounded by the precursor film pattern of the antistatic film on the substrate with a liquid containing a second metal and water thereby forming a precursor film pattern of the conductive film, and
baking the precursor film pattern of the antistatic film and the precursor film pattern of the conductive film thereby forming the antistatic film and the conductive film on the substrate.

11. A producing method for an electron source according to claim 10, wherein a surface of the precursor film pattern has a contact angle to water equal to or larger than twice of a contact angle to water of a surface of the substrate.

12. A producing method for an electron source according to claim 10, wherein the liquid containing the second metal and water is provided by an ink jet method.

13. An image display apparatus comprising an electron source, produced by a producing method for an electron source according to claim 10, and, in an opposed relationship thereto, a substrate having an image display member which displays an image by an irradiation with electrons from the electron source.
